(19) United States
(12) Patent Application Publication
(10) Pub. No.: US 2006/0164701 A1
(43) Pub. Date: Jul. 27, 2006

(54) Image correcting apparatus, image correcting program storage medium, data conversion apparatus, and data conversion program storage medium

(75) Inventors: Yasuharu Aoki, Kanagawa (JP); Akira Watanabe, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/339,578

(22) Filed: Jan. 26, 2006

(30) Foreign Application Priority Data
Jan. 26, 2005 (JP) 2005-018612

(51) Int. Cl. G03F 3/08

(52) U.S. Cl. 358/518

(57) ABSTRACT

In an image correcting apparatus, an image analyzing section performs a predetermined image analysis for an image. An image correction section applies an image correction to the image of interest in accordance with a result of the image analysis by the image analyzing section. A designation section performs a designation of defining contents of the image correction directly or indirectly to the image through an operation. A processing control section causes the image correction section to apply correction of contents defined by the designation of the designation section to the image subjected to the designation of the designation section.

### BACKGROUND OF THE INVENTION

1. Field of the Invention

The present invention relates to an image correcting apparatus for applying image correcting processing to an image, an image correcting program storage medium storing an image correcting program, a data conversion apparatus for converting data representative of a page in which images are arranged into data representing the page in form of an image having a single unitary body, and a data conversion program storage medium storing a data conversion program.

2. Description of the Related Art

Recently, as a technology of an image taking apparatus, which is typically represented by a digital camera, and an image reading apparatus, which is typically represented by a scanner, is developed, DTP's (Desk Top Publishing) have come into wide use in which photographed color images and read color images are taken into computers so that printed matters are produced using the taken color images as materials.

In the color images taken into the computers, in order that an image looks more beautiful, it happens that an image correction is applied to the image. In order to efficiently apply the image correction to page description data of the data format PDF and PostScript (registered trademark), which include many images, there is proposed an image correcting apparatus having a so-called auto-setup function in which properties of images of the page description data are estimated, and a suitable image correction is automatically applied to every image in accordance with the estimate information (for example, cf. Japanese Patent Application Laid Open Gazette Tokukai 2004-274720).

However, according to the auto-setup function disclosed in Japanese Patent Application Laid Open Gazette Tokukai 2004-274720, it happens that an erroneous estimation is performed in a process of estimating properties of an image for an image correction, and as a result, an image correction, which is against a user's intention, is applied to the image. In the auto-setup function as mentioned above, as a result that the image correction is performed in accordance with the erroneous estimation, for example, in the event that a plurality of images is arranged in a page, and one of the images is erroneously corrected to a color that is against the user's intention, there is a need for a user to have either one of options that the user tolerates the color of the image of interest, and that the user cancels the color correction using the auto-setup function and performs a color correction for each of the plurality of images using a retouching software. Accordingly, while the image correction using the auto-setup function disclosed in Japanese Patent Application Laid Open Gazette Tokukai 2004-274720 has such an advantage that it is possible to efficiently perform the image correction for page description data of the data format, which include many images, it is an image correction lacking in adaptability, from the view point that the image correction is performed to meet a user's intention.

### SUMMARY OF THE INVENTION

In view of the foregoing, it is an object of the present invention to provide an image correcting apparatus capable of efficiently performing an image correction and also capable of performing an adaptable image correction to meet a user's intention, an image correcting program storage medium storing an image correcting program, a data conversion apparatus, and a data conversion program storage medium storing a data conversion program.

To achieve the above-mentioned object, the present invention provides an image correcting apparatus comprising:

an image analyzing section that performs a predetermined image analysis for an image;

an image correction section that applies an image correction to the image of interest in accordance with a result of the image analysis by the image analyzing section;

a designation section that performs a designation of defining contents of the image correction directly or indirectly to the image through an operation; and

a processing control section that causes the image correction section to apply correction of contents defined by the designation of the designation section to the image subjected to the designation of the designation section.

The image correcting apparatus according to the present invention as mentioned above has a function of performing a designation for defining contents of an image correction to apply the image correction based on the designation as well as a function of applying the image correction according to the result of the image analysis to the image of interest. This feature makes it possible to apply the adaptable image correction to meet a user's intention to only the image of interest, even in the event that plural images to be subjected to the image correction exist, and the image correction, which is against the user's intention, is applied to one of the plural images.

In the image correcting apparatus according to the present invention as mentioned above, it is preferable that the designation section performs a designation of an analyzing result replacing an analyzing result of the image analysis, and

the processing control section causes the image correction section to apply image correction to an image subjected to a designation of the designation section, according to the analyzing result by the designation.

This feature makes it possible for a user to designate indirectly the image correction according to an analyzing result through designation of the analyzing result.

In the image correcting apparatus according to the present invention as mentioned above, it is preferable that the image analyzing section performs a scene analysis to estimate a scene of an image,

the image correction section applies an image correction to the image of interest in accordance with a result of the scene analysis by the image analyzing section, and

the designation section performs a designation of defining contents of the image correction indirectly in such a manner that the designation section performs a designation of a scene replacing a result of a scene analysis by the image analyzing section.

Generally, in the scene analysis, the following three cases can be expected.

1. A case where the scene is properly estimated.

2. A case where the scene is erroneously estimated.

3. A case where only information, which can be obtained from a result of the scene analysis, is insufficient for the estimation of the scene.

As an aspect of the scene analysis, it is known that when the conditions of specifying the scene are loosened to reduce an occurrence of a case where an estimation of the scene is difficult, it is easy that the erroneous estimation of the scene happens, while there is increased a possibility that the scene of an image is properly estimated.

According to the image correcting apparatus of the present invention, it is possible to designate the image correction according to the analyzing result of the designated scene, indirectly, through the designation of the scene for the image. Thus, this feature makes it possible to apply the image correction to meet a user's intention to the image subjected to the erroneous estimation of the scene. In the scene analysis, in the event that the erroneous estimation of the scene is carried out, so that the image correction, which is against the user's intention, is performed, it is possible for even a user unskilled in the image correction to easily recognize the fact that the erroneous image correction is performed. Thus, it is possible for even a user unskilled in the image correction to discriminate only the images that are subjected to the erroneous estimation of the scene, so that the image correcting apparatus of the present invention is used to apply the image correction to meet the user's intention.

In the image correcting apparatus according to the present invention as mentioned above, it is preferable that the image correction section applies a correction processing related to colors to an image, and

the designation section performs a designation of defining contents of the correction processing related to colors directly.

This feature makes it possible to perform the correction processing for alteration to colors to meet a user's intention for the image of interest.

To achieve the above-mentioned object, the present invention provides an image correcting program storage medium storing an image correcting program which causes a computer to operate as an image correcting apparatus, when the image correcting program is incorporated into the computer and is executed, the image correcting apparatus comprising:

an image analyzing section that performs a predetermined image analysis for an image;

an image correction section that applies an image correction to the image of interest in accordance with a result of the image analysis by the image analyzing section;

a designation section that performs a designation of defining contents of the image correction directly or indirectly to the image through an operation; and

a processing control section that causes the image correction section to apply correction of contents defined by the designation of the designation section to the image subjected to the designation of the designation section.

When the image correcting program stored in the image correcting program storage medium is executed in a computer, it is possible to operate the computer as the image correcting apparatus.

The image correcting program stored in the image correcting program storage medium includes all the aspects corresponding to those of the image correcting apparatus.

With respect to the structural elements such as the image analyzing section constituting the image correcting program related to the present invention, it is acceptable that function of one structural element is implemented by one program part, function of one structural element is implemented by a plurality of program parts, or alternatively functions of a plurality of structural elements are implemented by one program part. Further, it is acceptable that those structural elements are executed by oneself or by instruction to another program or program parts incorporated into a computer.

To achieve the above-mentioned object, the present invention provides a data conversion apparatus that converts first data wherein a page, in which images are arranged, is represented by describing an arrangement of the images, into second data representing the page in form of an image having a single unitary body, the data conversion apparatus comprising:

an image analyzing section that performs a predetermined image analysis for the images in which the arrangement of the images is described by the first data;

an image correction section that applies an image correction to the images of interest in accordance with a result of the image analysis by the image analyzing section;

a designation section that performs a designation of defining contents of the image correction directly or indirectly to the images, in which the arrangement of the images is described by the first data, through an operation;

a processing control section that causes the image correction section to apply correction of contents defined by the designation of the designation section to the images subjected to the designation of the designation section; and

a data creating section that creates the second data representing the page in form of an image having a single unitary body, in which the images corrected by the image correction section are arranged in accordance with the arrangement described by the first data.

The data conversion apparatus according to the present invention as mentioned above has a function of performing a designation for defining contents of an image correction to apply the image correction based on the designation as well as a function of applying the image correction according to the result of the image analysis to the image of interest, which is represented by the first data. This feature makes it possible to apply the adaptable image correction to meet a user's intention to only the image of interest, even in the event that plural images to be subjected to the image correction exist, and the image correction, which is against the user's intention, is applied to one of the plural images.

To achieve the above-mentioned object, the present invention provides a data conversion program storage medium storing a data conversion program which causes a computer to operate as a data conversion apparatus, when the data conversion program is incorporated into the computer and is executed, the data conversion program converting first data wherein a page, in which images are arranged, is represented by describing an arrangement of the images, into second data representing the page in form of an image having a single unitary body, the data conversion apparatus comprising:

an image analyzing section that performs a predetermined image analysis for the images in which the arrangement of the images is described by the first data;

an image correction section that applies an image correction to the images of interest in accordance with a result of the image analysis by the image analyzing section;

a designation section that performs a designation of defining contents of the image correction directly or indirectly to the images, in which the arrangement of the images is described by the first data, through an operation;

a processing control section that causes the image correction section to apply correction of contents defined by the designation of the designation section to the images subjected to the designation of the designation section; and

a data creating section that creates the second data representing the page in form of an image having a single unitary body, in which the images corrected by the image correction section are arranged in accordance with the arrangement described by the first data.

When the data conversion program stored in the data conversion program storage medium is executed in a computer, it is possible to operate the computer as the data conversion apparatus.

The data conversion program stored in the data conversion program storage medium includes all the aspects corresponding to those of the data conversion apparatus.

With respect to the structural elements such as the image analyzing section constituting the data conversion program related to the present invention, it is acceptable that function of one structural element is implemented by one program part, function of one structural element is implemented by a plurality of program parts, or alternatively functions of a plurality of structural elements are implemented by one program part. Further, it is acceptable that those structural elements are executed by oneself or by instruction to another program or program parts incorporated into a computer.

### BRIEF DESCRIPTION OF THE DRAWINGS

FIG. 1 is a construction view of an image processing system, to which an embodiment of a data conversion apparatus of the present invention is applied.

FIG. 2 is a perspective view of a personal computer that is operative in form of an embodiment of a data conversion apparatus of the present invention.

FIG. 3 is a hardware structural view of the personal computer shown in FIG. 2.

FIG. 4 is a view useful for understanding a data conversion program stored in a data conversion program storage medium according to an embodiment of the present invention.

FIG. 5 is a functional block diagram of elements for operating the personal computer shown in FIG. 2 and FIG. 3 in form of an embodiment of a data conversion apparatus of the present invention.

FIG. 6 is an explanatory view useful for understanding a menu, which is displayed on a display screen of the personal computer shown in FIG. 2, when a user gives an instruction of contents of a color correction and an instruction of the scene.

FIG. 7 is a flowchart useful for understanding processing to be applied to page description data in which designation of contents of the color correction and designation of the scene are given to several images of a page.

### DETAILED DESCRIPTION OF PREFERRED EMBODIMENTS

Embodiments of the present invention will be described with reference to the accompanying drawings.

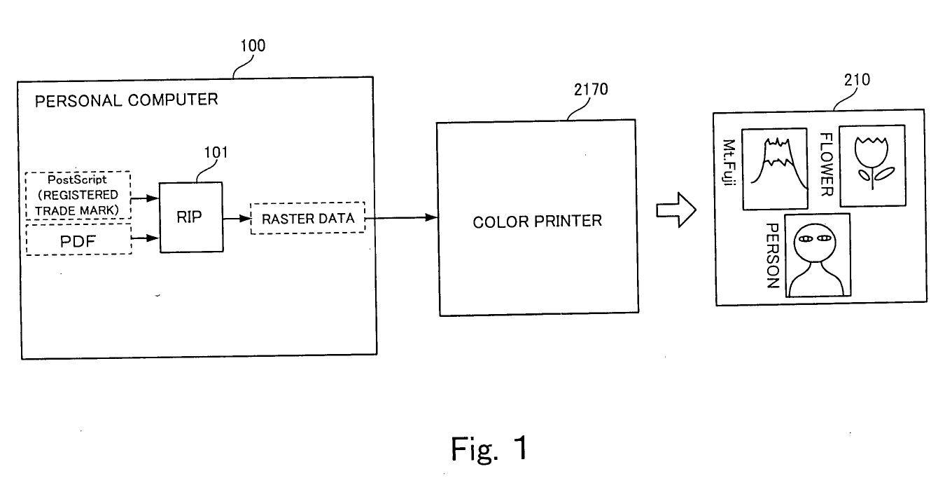

FIG. 1 is a construction view of an image processing system, to which an embodiment of a data conversion apparatus of the present invention is applied.

According to the image processing system, there is, applied a DTP in which a computer is used to create a printed mater. That is, according to the image processing system, a color printer 2170 outputs a page including characters and images, which are edited by an operator using a personal computer 100. The personal computer 100 receives, as materials of page editing, image data created through reading of an original image by a color scanner (not illustrated), and image data based on a photographic image obtained through photography by a digital camera (not illustrated). In the personal computer 100, an operator electronically edits a page including characters and images based on entered image data so as to create page description data representative of the edited page, and further performs set up for an image correction to color images of the thus edited page so that the color images look more beautiful. The thus created page description data is language data described in a so-called PDL (Page Description Language), and thus it is impossible for the color printer 2170 to output the page description data as it is. Accordingly, the page description data is fed to a RIP 101 to apply an image correction based on the set up of the image correction as mentioned above and then converted into raster data capable of being outputted by the color printer 2170. The raster data after conversion is fed to the color printer 2170 to create an output image 210 in accordance with the entered raster data.

Thus, the personal computer 100 serves as the main part in the image processing system shown in FIG. 1 through performing the set up of the image correction, the execution of the image correction thus set up, the data conversion processing from the page description data to the raster data capable of being outputted by the color printer 2170, as well as editing of a page including characters and images and the control of the color printer 2170. A feature of the data conversion apparatus according to the embodiment of the present invention in the image processing system resides in contents of image correction processing and data conversion processing, which are executed by the personal computer 100. The personal computer 100 serves as the data conversion apparatus according to the embodiment of the present invention and also as the image correction apparatus according to the embodiment of the present invention. Hereinafter, there will be explained the personal computer 100, particularly, the RIP 101 that is the main parts of image correction processing and data conversion processing.

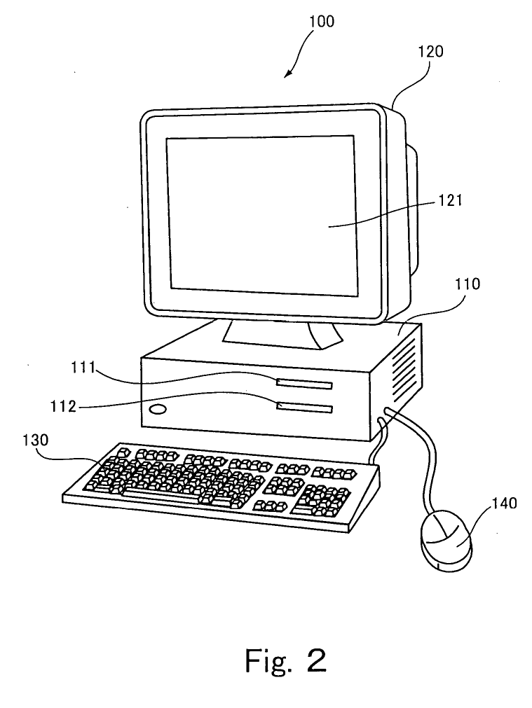

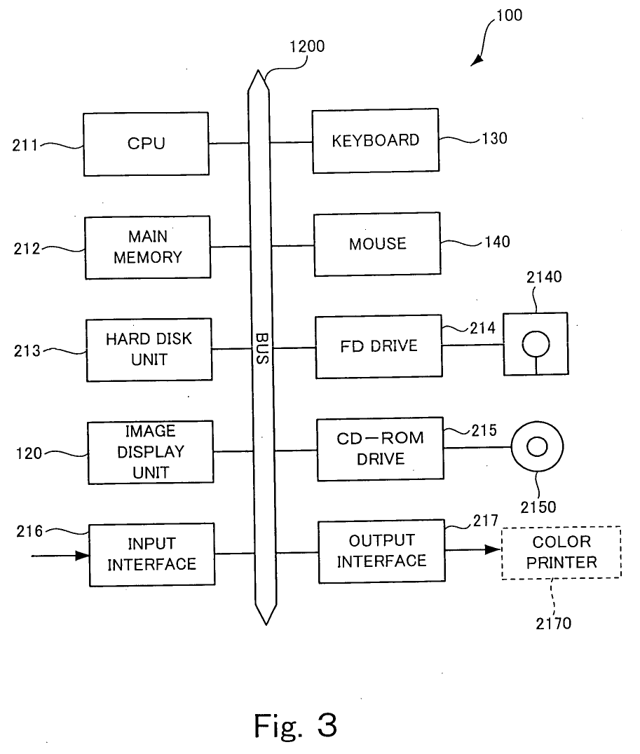

FIG. 2 is a perspective view of a personal computer that is operative in form of an embodiment of a data conversion apparatus of the present invention. FIG. 3 is a hardware structural view of the personal computer shown in FIG. 2.

The personal computer 100 comprises, on an external appearance, a main frame unit 110 incorporating therein a CPU, a RAM memory, a hard disk and the like, an image display unit 120 for displaying an image on a display screen 121 in accordance with an instruction from the main frame unit 110, a keyboard 130 for inputting various sorts of information such as user's instruction and character information to the main frame unit 110 in accordance with a key operation, and a mouse 140 for inputting an instruction according to, for example, an icon and the like, through designation of an optional position on the display screen 121, the icon and the like being displayed on the position on the display screen 121.

The main frame unit 110 has a flexible disk-mounting slot 111 for mounting a flexible disk (FD), and a CD-ROM mounting slot 112 for mounting a CD-ROM. Inside of the main frame unit 110, there are provided a FD drive and a CD-ROM drive, which drive the mounted FD and CD-ROM, respectively.

The main frame unit 110 comprises, as shown in FIG. 3, a CPU 211 for executing a various types of program, a main memory 212 in which a program stored in a hard disk unit 213 is read out and developed for execution by the CPU 211, the hard disk unit 213 for saving various types of programs and data, a flexible disk (FD) drive 214 for accessing a flexible disk 2140 mounted thereon, and a CD-ROM drive 215 for accessing a CD-ROM 2150 mounted thereon. These various types of elements are connected via a bus 1200 to the image display unit 120, the keyboard 130 and the mouse 140. Outside the personal computer 100, there are provided the color printer 2170 for outputting images. The personal computer 100 incorporates therein an output interface 217 to transmit output data from the personal computer 100 to the color printer 2170 and others. The personal computer 100 incorporates therein an input interface 216 to input page description data through connection with external equipment such as scanner and digital camera (not illustrated). The output interface 217 and the input interface 216 are also connected via the bus 1200 to the above-mentioned various elements, which constitute the hardware of the personal computer 100.

According to the personal computer 100, a user of the personal computer 100 can save the page description data into the hard disk unit 213 through entry of the same from the input interface 216. Also the user of the personal computer 100 can save the page description from the FD 2140 and the CD-ROM 2150, which store the image data, via the FD drive 214 and the CD-ROM drive 215, respectively, into the hard disk unit 213. According to the personal computer 100, which serves as the data conversion apparatus of the present embodiment, the page description data of the processing object is the page description data saved into the hard disk unit 213 in the manner as mentioned above. However, it is acceptable that the data conversion apparatus of the present invention uses the page description data saved in the FD 2140 and the CD-ROM 2150, which are mounted on the FD drive 214 and the CD-ROM drive 215, respectively, but not restricted to the hard disk unit 213.

Next, there will be explained an embodiment of a data conversion program storage medium storing a data conversion program, of the present invention.

In the event that the data conversion program is stored in, for example, the CD-ROM 2150, when the CD-ROM 2150 is mounted on the main frame 110 through the CD-ROM mounting slot 112, the CD-ROM drive 215 installs the data conversion program stored in the CD-ROM 2150 in the hard disk unit 213 of the personal computer 100. When the data conversion program installed in the hard disk unit 213 is activated, the personal computer 100 serves as an embodiment of the data conversion apparatus of the present invention.

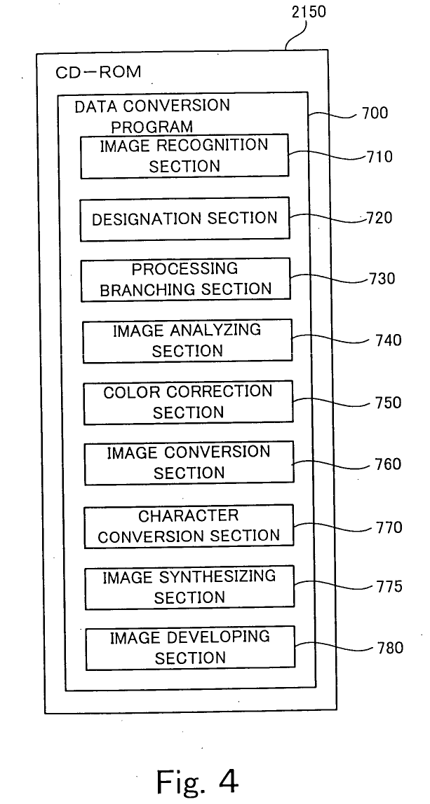

FIG. 4 is a view useful for understanding a data conversion program stored in a data conversion program storage medium according to an embodiment of the present invention.

The CD-ROM 2150 stores therein a data conversion program 700. As the storage medium storing the data conversion program 700, it is possible to adopt various types of storage medium such as not only the CD-ROM 2150 shown in FIG. 4 but also the hard disk unit 213 and the FD 2140 shown in FIG. 3 and DVD and MO (not illustrated in FIG. 3).

The data conversion program 700 is executed in the personal computer 100 shown in FIG. 2 and FIG. 3 so as to cause the personal computer 100 to serve as an embodiment of the present invention, as mentioned above. The data conversion program 700 comprises an image recognition section 710, a designation section 720, a processing branching section 730, an image analyzing section 740, a color correction section 750, an image conversion section 760, a character conversion section 770, an image synthesizing section 775, and an image developing section 780.

Details of contents of every element of the data conversion program 700 will be described later.

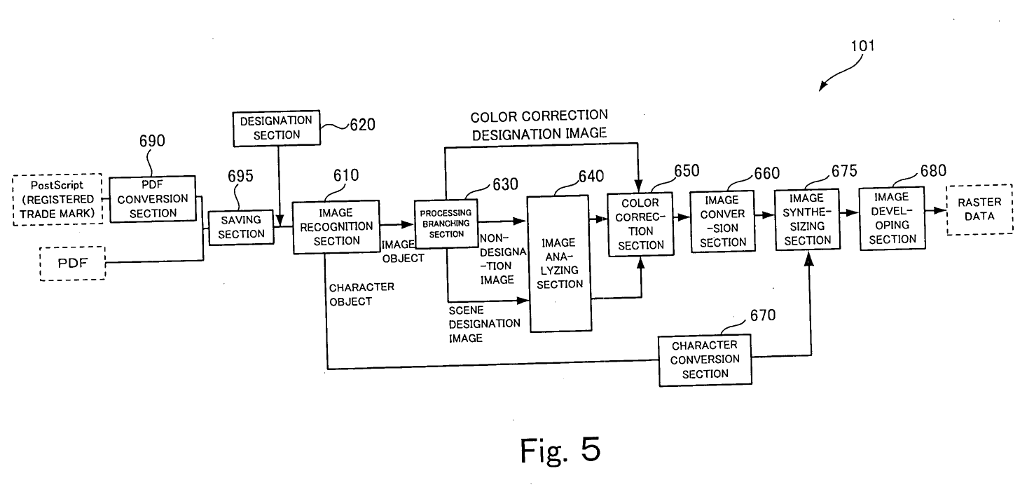

FIG. 5 is FIG. 5 is a functional block diagram of elements for operating the personal computer shown in FIG. 2 and FIG. 3 in form of an embodiment of a data conversion apparatus of the present invention.

When the data conversion program 700 shown in FIG. 4 is installed in the personal computer 100 shown in FIG. 2 and FIG. 3, constructed on the personal computer 100 are an image recognition section 610, a designation section 620, a processing branching section 630, an image analyzing section 640, a color correction section 650, an image conversion section 660, a character conversion section 670, an image synthesizing section 675, and an image developing section 680, which are shown in FIG. 5. Those elements constitutes the RIP 101 for converting the page description data into raster data for output, so that the data conversion program 700 causes the personal computer 100 to serve as an embodiment of a data conversion apparatus of the present invention. The image recognition section 610, the designation section 620, the processing branching section 630, the image analyzing section 640, the color correction section 650, the image conversion section 660, the character conversion section 670, the image synthesizing section 675, and the image developing section 680 are constructed on the personal computer 100 by the image recognition section 710, the designation section 720, the processing branching section 730, the image analyzing section 740, the color correction section 750, the image conversion section 760, the character conversion section 770, the image synthesizing section 775, and the image developing section 780, of the data conversion program 700 shown in FIG. 4, respectively. Accordingly, all the elements of FIG. 4 correspond to the associated elements of FIG. 5, respectively. However, the elements of FIG. 5 are different from the elements of FIG. 4 in the following point. The elements of FIG. 5 are constructed by a combination of the hardware of the personal computer 100 shown in FIG. 1 and FIG. 2 and an OS and an application program, which are executed in the personal computer 100. On the other hand, the elements of the data conversion program 700 shown in FIG. 4 are constructed by only the application program.

A program excepting the image developing section 780 from the data conversion program 700 corresponds to the embodiment of the data conversion program stored in the data conversion program storage medium of the present invention. In the data conversion apparatus of the present embodiment, an apparatus comprising all the elements as mentioned above excepting the image developing section 680 corresponds to the embodiment of the data conversion apparatus of the present invention. According to the present embodiment, the personal computer 100, which serves as the embodiment of the data conversion apparatus of the present invention, also serves as the embodiment of the image correcting apparatus of the present invention.

According to the present embodiment, the image analyzing section 640 corresponds to an example of the image analyzing section referred to in the present invention, the color correction section 650 corresponds to an example of the image correction section referred to in the present invention, the designation section 620 corresponds to an example of the designation section referred to in the present invention, the processing branching section 630 corresponds to an example of the processing control section referred to in the present invention, and the image developing section 680 corresponds to an example of the data creating section referred to in the present invention.

Hereinafter, there will be explained all the elements shown in FIG. 5 and the functions of the elements.

A PDF conversion section 690 converts page description data of a data format of PostScript (registered trade mark), of page description data of a data format of PostScript (registered trade mark) and a data format of PDF, which are saved in the hard disk unit 213, into the page description data of the data format of PDF, so that the page description data of interest in processing is unified to the page description data of the data format of PDF. A saving section 695 saves the unified page description data of the data format of PDF into the hard disk unit 213. Thus, the elements shown in FIG. 5 applies color correction processing to character object and image object of a page represented by the page description data of the data format of PDF in accordance with the image object.

First, there will be explained functions of all the elements show in FIG. 5 for page description data in which a user does not designate contents of color correction processing to any one of the image objects of a page.

First, the image recognition section 610 decides as to whether an object of a page is an image object and starts processing according to the object. In the event that the object is a character object, the character object is transmitted to the character conversion section 670 so as to be converted into a character object represented by character data of a color space suitable for the color printer 2170 shown in FIG. 3, and then transmitted to the image synthesizing section 675. On the other hand, in the event that the object of the page is an image object, the image object is transmitted to the processing branching section 630 in which it is regarded as non-designated image wherein contents of processing of the page are not designated, and further transmitted to the image analyzing section 640. The image analyzing section 640 performs an estimation of the scene on the image object, and an analysis of properties of colors of the image object. The color correction section 650 performs the color correction to meet the estimation of the scene on the image object. After the application of the color correcting processing as mentioned above, the image conversion section 660 converts the image object into an image object represented by image data of the color space meeting the color printer 2170 shown in FIG. 3, and then transmitted to the image synthesizing section 675. The image synthesizing section 675 synthesizes the character object with the image object and creates the page description data representative of a page including those objects.

The color correction processing based on the estimated scene, as mentioned above, is the color correction processing according to a so-called auto-setup function. According to the color correction processing as mentioned above, it happens that an erroneous estimation is performed in a process of estimating the scene of an image object, and as a result, a color correction, which is against a user's intention, is applied to the image object. Thus, there is a need to confirm as to whether an image of a page represented by the created page description data is corrected in color to an image of a color meeting a user's intention. According to the present embodiment, this confirmation work is carried out in such a manner that the image after the color correction is displayed on the display screen 121 of the personal computer 100 shown in FIG. 2, and a user checks as to whether the image is corrected in color to an image of a color meeting the user's intention.

Next, there will be explained the function of the designation section 620 shown in FIG. 5 to be carried out in accordance with a user's instruction, for the purpose of performing the color correction meeting the user's intention for the page description data wherein as a result of the confirmation work it becomes clear that an image correction, which is against the user's intention, will be carried.

First, a user selects page description data wherein as a result of the confirmation work through the auto-setup function it becomes clear that an image correction, which is against the user's intention, is carried out, from among PDF of page description data saved in the saving section 695. A page represented by the selected page description data is displayed on the display screen 121 of the personal computer 100 shown in FIG. 2, and a user starts an instruction of contents of a color correction and an instruction of scenes.

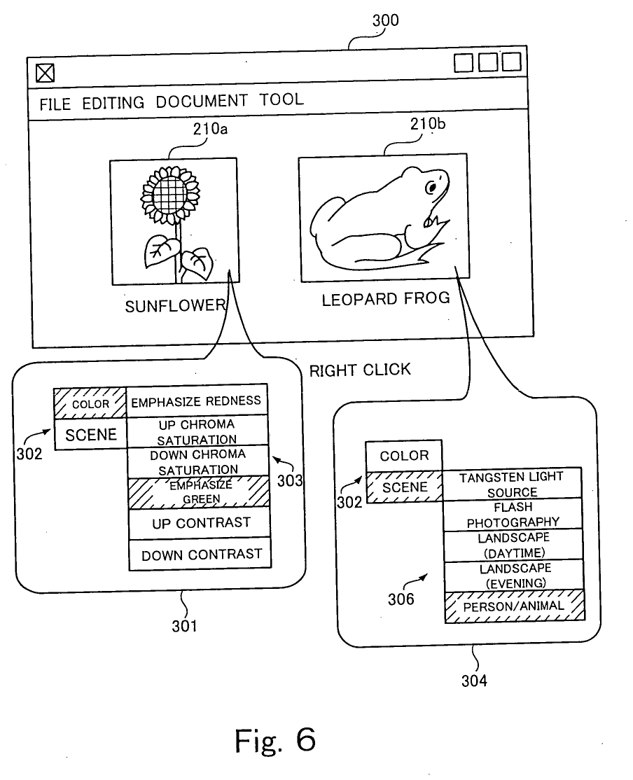

FIG. 6 is an explanatory view useful for understanding a menu, which is displayed on a display screen of the personal computer shown in FIG. 2, when a user gives an instruction of contents of a color correction and an instruction of the scene.

FIG. 6 shows, as an example of an image wherein as a result of the confirmation work through the auto-setup function it becomes clear that an image correction, which is against the user's intention, is carried out, there are shown a color image 210a indicative of “sunflower” and a color image 210b indicative of “leopard” in a window 300 for displaying a page represented by PDF of page description data. Hereinafter, there will be explained user's instruction of contents of a color correction and user's instruction of scenes, using this example.

Right clicking in an image of the window 300 causes a menu 302 to appear on the display screen 121. On the menu 302, there exist two sorts of choices as to selection of “color” for designating a desired color correction or selection of “scene” for designating a scene suitable for the image. FIG. 6 shows an example wherein right clicking is made in the color image 210a and an example wherein right clicking is made in the color image 210b, with blooming 301 and blooming 304, respectively. In FIG. 6, in order to clarify a relation between the menu 302 and the color image that is subjected to the right clicking, the blooming 301 and the blooming 304 are shown for the sake of convenience. Actually, however, the blooming 301 and the blooming 304 are not displayed on the display screen 121. In the menu 302 of the blooming 301, as shown in the figure with slashed lines, there is shown a state that “color” is selected from between the above-mentioned two sorts of choices. In the menu 302 of the blooming 304, as shown in the figure with slashed lines, there is shown a state that “scene” is selected.

In the state that it is selected that the color correction is designated, as shown in the blooming 301, there is displayed a menu 303 that is selectable in form of the color correction. According to this example, there is offered a state that “emphasize green” indicated with slashed lines in the figure is selected. Now left clicking of the mouse 140 may determine the selection (in this example, “emphasize green”) of the color correction, so that the content of the color correction instructed by the user is decided.

In the state that it is selected that the scene is designated, as shown in the blooming 304, there is displayed a menu 306 that is selectable in form of the scene. According to this example, there is offered a state that “person/animal” indicated with slashed lines in the figure is selected. Now left clicking of the mouse 140 may determine the selection (in this example, “person/animal”) of the scene, so that the scene instructed by the user is decided.

The designation section 620 shown in FIG. 5 performs embedding of attached information of instructing the content of the color correction, or the scene to the image of interest in accordance with the user's instruction. For example, as to the color image 210a indicative of “sunflower” shown in FIG. 6, the designation section 620 performs embedding of attached information of instructing the content of the color correction of “emphasize green”. And as to the color image 210b indicative of “leopard frog” shown in FIG. 6, the designation section 620 performs embedding of attached information of instructing the scene wherein “person/animal” is an object.

Next there will be explained, using a flowchart, processing to be applied to page description data in which designation of contents of the color correction and designation of the scene are given to several images of a page in accordance with contents of the color correction or the scene thus designated.

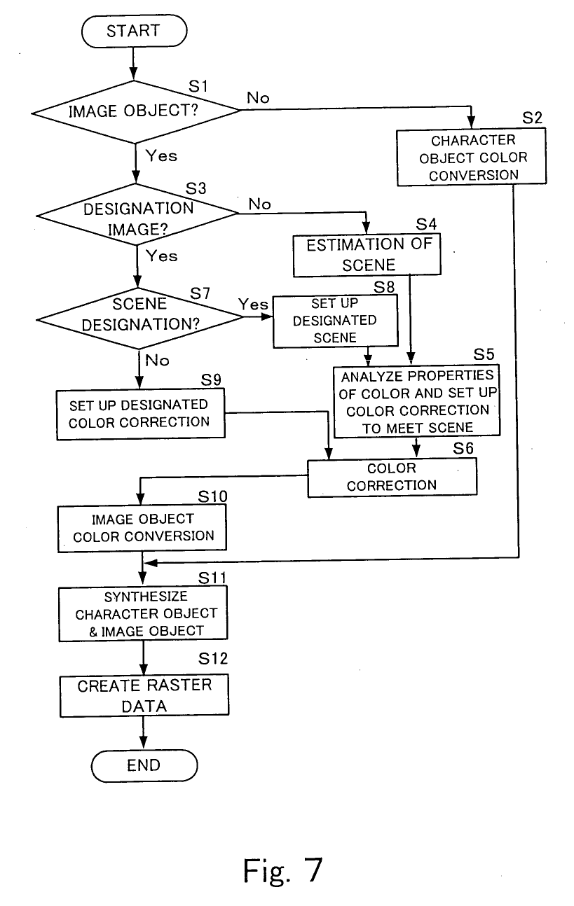

FIG. 7 is a flowchart useful for understanding processing to be applied to page description data in which designation of contents of the color correction and designation of the scene are given to several images of a page.

First, in step S1, the image recognition section 610 shown in FIG. 5 determines as to whether an object of a page is an image object. In the event that it is decided that the object is a character object (step S1: No), the character conversion section 670 converts the character object into a character object represented by character data of a color space suitable for the color printer 2170 shown in FIG. 3 (step S2). The converted character object is transmitted to the image synthesizing section 675 for synthesizing with the image object. On the other hand, when the image recognition section 610 decides the object of the page is the image object, (step S1: Yes), the processing branching section 630 determines as to whether the image object is concerned with the designation image into which the attached information of designating the contents of the color correction and the scene is embedded (step S3). When it is decided that the image object is not concerned with the designation image, the image analyzing section 640 performs an estimation of the scene on the image object (step S4). In step S5, the image analyzing section 640 performs an analysis of properties of colors of the image object, and the color correction section 650 sets up the color correction to meet the estimated scene. In step S6, the color correction section 650 performs the color correction thus set up. In case of the designation image, the processing branching section 630 determines as to whether the designation image is an image in which a scene of an image is already designated in the attached information (step S7). In the event that the processing branching section 630 determines that the designation image is an image in which a scene of an image is already designated (that is, the step S7: Yes), the image analyzing section 640 sets up the designated scene as the scene of the image (step S8). And the process goes to the step 5S in which the image analyzing section 640 performs an analysis of properties of colors of the designation image, and the color correction section 650 sets up the color correction to meet the designated scene. The color correction section 650 applies the color correction set up so as to obtain an image of colors meeting the designated scene (step S6). On the other hand, in case of the designation image in which the content of the color correction is designated (step S7: No), the color correction section 650 sets up the content of the color correction thus designated (step S9). And the process goes to the step S6 in which the designated color correction is applied. Thus, the image conversion section 660 converts the image object, which is subjected to the color correction processing in the manner as mentioned above, into the image object represented by image data of the color space suitable for the color printer 2170 shown in FIG. 3 (step S10). The converted image object is transmitted to the image synthesizing section 675. The image synthesizing section 675 synthesizes the image object and the above-mentioned character object (step S11) and generates page description data representative of a page including those objects. The page description data, which is generated by the image synthesizing section 675, is transmitted to the image developing section 680. In step S12, the image developing section 680 converts the page description data into the raster data. The converted raster data is transmitted via the output interface 217 shown in FIG. 2 to the color printer 2170 shown in FIG. 3. The color printer 2170 creates the output image such as the color image 210, which is shown in FIG. 1, by way of example.

The above-mentioned description is concerned with an explanation for processing of all elements shown in FIG. 5 for the page description data which is subjected to embedding of attached information for designating color correction and scene to several images of a page.

Thus, according to the computer 100, which serves as a data conversion apparatus of the present embodiment, the color correction processing according to the auto-setup function applies a color correction processing meeting a user's intention to the image object to which the color correction against a user's intention is applied, and applies the color correction processing according to the auto-setup function to other image objects. As a result, according to the data conversion apparatus of the present embodiment, it is possible to perform adaptable color correction processing meeting a user's intention, while making good use of the advantage of the auto-setup function.

As mentioned above, according to an image correcting apparatus, an image correcting program storage medium storing an image correcting program, a data conversion apparatus, and a data conversion program storage medium storing a data conversion program, of the present invention, it is possible to efficiently perform an image correction and also to perform an adaptable image correction to meet a user's intention.

While the present invention has been described with reference to the particular illustrative embodiments, it is not to be restricted by those embodiments but only by the appended claims. It is to be appreciated that those skilled in the art can change or modify the embodiments without departing from the scope and sprit of the present invention.

What is claimed is:

1. An image correcting apparatus comprising:
an image analyzing section that performs a predetermined image analysis for an image;
an image correction section that applies an image correction to the image of interest in accordance with a result of the image analysis by the image analyzing section;
a designation section that performs a designation of defining contents of the image correction directly or indirectly to the image through an operation; and
a processing control section that causes the image correction section to apply correction of contents defined by the designation of the designation section to the image subjected to the designation of the designation section.

2. An image correcting apparatus according to claim 1, wherein the designation section performs a designation of an analyzing result replacing an analyzing result of the image analysis, and
the processing control section causes the image correction section to apply image correction to an image subjected to a designation of the designation section, according to the analyzing result by the designation.

3. An image correcting apparatus according to claim 1, wherein the image analyzing section performs a scene analysis to estimate a scene of an image,
the image correction section applies an image correction to the image of interest in accordance with a result of the scene analysis by the image analyzing section, and
the designation section performs a designation of defining contents of the image correction indirectly in such a manner that the designation section performs a designation of a scene replacing a result of a scene analysis by the image analyzing section.

4. An image correcting apparatus according to claim 1, wherein the image correction section applies a correction processing related to colors to an image, and
the designation section performs a designation of defining contents of the correction processing related to colors directly.

5. An image correcting program storage medium storing an image correcting program which causes a computer to operate as an image correcting apparatus, when the image correcting program is incorporated into the computer and is executed, the image correcting apparatus comprising:
an image analyzing section that performs a predetermined image analysis for an image;
an image correction section that applies an image correction to the image of interest in accordance with a result of the image analysis by the image analyzing section;
a designation section that performs a designation of defining contents of the image correction directly or indirectly to the image through an operation; and
a processing control section that causes the image correction section to apply correction of contents defined by the designation of the designation section to the image subjected to the designation of the designation section.

6. A data conversion apparatus that converts first data wherein a page, in which images are arranged, is represented by describing an arrangement of the images, into second data representing the page in form of an image having a single unitary body, the data conversion apparatus comprising:
an image analyzing section that performs a predetermined image analysis for the images in which the arrangement of the images is described by the first data;
an image correction section that applies an image correction to the images of interest in accordance with a result of the image analysis by the image analyzing section;
a designation section that performs a designation of defining contents of the image correction directly or indirectly to the images, in which the arrangement of the images is described by the first data, through an operation;
a processing control section that causes the image correction section to apply correction of contents defined by the designation of the designation section to the images subjected to the designation of the designation section; and
a data creating section that creates the second data representing the page in form of an image having a single unitary body, in which the images corrected by the image correction section are arranged in accordance with the arrangement described by the first data.

7. A data conversion program storage medium storing a data conversion program which causes a computer to operate as a data conversion apparatus, when the data conversion program is incorporated into the computer and is executed, the data conversion program converting first data wherein a page, in which images are arranged, is represented by describing an arrangement of the images, into second data representing the page in form of an image having a single unitary body, the data conversion apparatus comprising:
an image analyzing section that performs a predetermined image analysis for the images in which the arrangement of the images is described by the first data;
an image correction section that applies an image correction to the images of interest in accordance with a result of the image analysis by the image analyzing section;
a designation section that performs a designation of defining contents of the image correction directly or indirectly to the images, in which the arrangement of the images is described by the first data, through an operation;
a processing control section that causes the image correction section to apply correction of contents defined by the designation of the designation section to the images subjected to the designation of the designation section; and
a data creating section that creates the second data representing the page in form of an image having a single unitary body, in which the images corrected by the image correction section are arranged in accordance with the arrangement described by the first data.
